(19) United States
(12) Patent Application Publication
(10) Pub. No.: US 2024/0321663 A1
(43) Pub. Date: Sep. 26, 2024

(54) HIGH-PERFORMANCE STRESS BUFFER DIE-COAT AND DEVICES AND PROCESSES IMPLEMENTING THE SAME

(71) Applicant: WOLFSPEED, INC., Durham, NC (US)

(72) Inventors: Afshin DADVAND, Durahm, NC (US); Dev BALARAMAN, Durham, NC (US)

(21) Appl. No.: 18/187,924

(22) Filed: Mar. 22, 2023

(51) Int. Cl. H01L 23/31; B05D 1/12; B05D 1/26; H01L 21/56; H01L 23/00; H01L 23/29

(52) U.S. Cl. CPC H01L 23/3135; B05D 1/12; B05D 1/26; H01L 21/565; H01L 23/291; H01L 23/296; H01L 24/32; H01L 24/48; B05D 2430/00; B05D 2505/50; B05D 2601/00; H01L 2224/32245; H01L 2224/48245; H01L 2924/12032; H01L 2924/13091

(57) ABSTRACT

A device may include device parts, a composite coating material arranged on one or more of the device parts, and a molding compound arranged on and/or around one or more of the device parts. Moreover, the device may include where the composite coating material may include a polymer matrix including and/or incorporating ceramic particles.

### BACKGROUND OF THE DISCLOSURE

Currently, there are a number of materials used as die-coats. However, these die-coat materials provide only limited performance benefits.

Accordingly, what is needed is a stress buffer coat material providing improved performance benefits, devices implementing a stress buffer coat material providing improved performance benefits, and/or the like as described herein.

### SUMMARY OF THE DISCLOSURE

The foregoing needs are met, to a great extent, by the disclosure, wherein a high-performance stress buffer die-coat, a device implementing a high-performance stress buffer die-coat, a process of manufacturing high-performance stress buffer die-coat, a process of manufacturing a device having a high-performance stress buffer die-coat and/or the like are provided.

In one aspect, a device that includes device parts. The device in addition includes a composite coating material arranged on one or more of the device parts. The device moreover includes a molding compound arranged on and/or around one or more of the device parts. The device also includes where the composite coating material includes a polymer matrix including and/or incorporating ceramic particles.

In one aspect, a process includes providing device parts. The process in addition includes arranging a composite coating material on one or more of the device parts. The process moreover includes arranging a molding compound on and/or around one or more of the device parts. The process also includes where the composite coating material includes a polymer matrix including and/or incorporating ceramic particles.

In one aspect, a composite coating material includes ceramic particles. The composite coating material in addition includes a polymer matrix including and/or incorporating the ceramic particles.

In one aspect, a process includes providing a polymer matrix. The process in addition includes incorporating ceramic particles into the polymer matrix.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a cross-sectional view of a device having device parts with a hybrid composite coating material arranged thereon according to aspects of the disclosure.

FIG. 2 illustrates a cross-sectional view of a device having different device parts with a hybrid composite coating material arranged thereon according to aspects of the disclosure.

FIG. 3 illustrates a cross-sectional view of a device having different device parts with a hybrid composite coating material arranged thereon according to aspects of the disclosure.

FIG. 4 illustrates a cross-sectional view of the composite coating material arranged on the device parts of the device according to aspects of the disclosure.

FIG. 5 illustrates a top view of the device implementing the device parts according to aspects of the disclosure.

FIG. 6 illustrates a cross-sectional view of the device implementing the device parts according to aspects of the disclosure.

FIG. 7 illustrates a cross-sectional view of the device implementing the device parts according to aspects of the disclosure.

FIG. 8 illustrates a process of manufacturing a device according to aspects of the disclosure.

### DETAILED DESCRIPTION

The disclosure will now be described with reference to the drawing figures, in which like reference numerals refer to like parts throughout. Aspects of the disclosure advantageously provide a high-performance stress buffer die-coat, a device implementing a high-performance stress buffer die-coat, a process of manufacturing high-performance stress buffer die-coat, a process of manufacturing a device having a high-performance stress buffer die-coat and/or the like.

The disclosure relates to a high-performance stress buffer die-coat. The disclosure further relates to a device implementing a high-performance stress buffer die-coat. The disclosure further relates to a process of manufacturing high-performance stress buffer die-coat. The disclosure further relates to a process of manufacturing a device having a high-performance stress buffer die-coat.

Various devices utilize molding compounds to protect different parts of the devices thereof. However, the interfacial thermomechanical stress posed by the molding compounds (MCs) on the different parts of the devices, such as a die, a chip, and/or the like can result in performance and mechanical degradation and failures such as cracks in various portions of the devices, such as a passivation layer, and/or the like. Moreover, the interfacial thermomechanical stress posed by the molding compounds (MCs) can result in deformation, delamination, and/or the like of metal electrodes, wire bonds, and/or the like.

This interfacial stress, which is typically produced by mismatch in coefficient of thermal expansion (CTE) of the molding compound and the different parts of the devices, such as the die, the chip, a leadframe, and/or the like, can be aggravated when the different parts of the devices, such as the die, the package, and/or the like experience a high operational temperature condition, a high operational testing temperature condition, and/or the like, for example temperature cycling (TC) tests, or high temperature reverse bias (HTRB) tests, and/or the like.

In some cases, the edges of the die typically carry a large portion of the stress and are prone to higher rate of failures such as metal delamination, metal deformation, electrode metal delamination, electrode metal deformation, cracks in the passivation layer, cracks in a silicon nitride (SiNx) passivation layer, and/or the like. In particular, these issues may be especially prevalent in power transistors, such as power MOSFETS.

Attempts have been made to mitigate this type of interfacial stress through coating the entire die (and perhaps the leadframe and/or the wire bonds) with a buffer layer having certain material properties. Currently, polyimides are typically used as stress buffer coat (die-coat) materials. In some cases, the die-coats have been also used in hybrid with a small amount of fillers (˜1% weight), such as silica. However, these die-coat materials fail to provide both good thermal conductivities and also efficiently act as stress buffer layer at the same time. In this regard, these die-coat materials incorporating thermally conductive and electrically insulating ceramic fillers may be beneficial as buffer layer. However, most of these ceramic fillers are typically hard, abrasive, and/or high dielectric constant (high-K) materials imparting different limitations or other possible failures.

Aspects of the disclosure provide a coating material and process that may include a hybrid composite of a polymer matrix, such as a polyimide, a silicon, fluoropolymer, copolymers of polyimide-silicon, and/or the like incorporating hexagonal boron-nitride (h-BN) particles or like property ceramic particles, such as 5 nm to 5 μm sized h-BN particles, as filler. In other aspects, the polymer matrix may include particles of SiNx, Aluminum nitride (AlN), Beryllium oxide (BeO), diamond, and/or the like. The disclosed hybrid composite can efficiently reduce failures associated with interfacial stress during high temperature operation, such as thermal cycling (TC), high temperature reverse bias (HTRB), and/or the like.

Among ceramic fillers, h-BN is a comparatively soft, low-density material and also possess a very high in-plane and relatively high out-of-plane thermal conductivity up to 600 W/mK and 30 W/mK, respectively. Moreover, h-BN can dissipate heat in both directions without any or with negligible localized heat that results in minimizing the CTE-mismatch-induced interfacial stress, generated during high temperature operation conditions, testing conditions, and/or the like, such as, for example, temperatures exceeding 150 degrees C.

The disclosed hybrid composite may include h-BN in forms of nano-particles, microparticles, nanotubes (NT), pallets, and/or the like. Moreover, the disclosed hybrid composite may be implemented in combination with other fillers. Further, the disclosed hybrid composite may be deposited via different methods, such as by dispense, inkjet, spray coat, screen print, and/or the like. Additionally, the disclosed hybrid composite may be then cured. For example, the disclosed hybrid composite may—include degassing at 50-100 degrees C. for 30-60 minutes, may be cured at 150-250 degrees C. for 30-60 minutes.

In aspects, the h-BN ceramic may be mixed with the polymer matrix, such as a polyimide and/or the like. In aspects, the h-BN ceramic can be processed to have a surface functionalization of hBN particles, followed by grafting to the polymer, such as a monomer, an oligomer, and/or the like, which results in a uniform and/or more uniform distribution of h-BN particles.

In aspects, a thin layer of the grafted h-BN hybrid composite may be capable of uniformly or more uniformly distributing the interfacial thermomechanical stress, such as posed by the molding compound, as well as the heat across the coated area and efficiently prevent or significantly mitigate the associated failures such as ratcheting-induced metal delamination, ratcheting-induced metal deformation, passivation layer cracking, SiNx passivation layer cracking, and/or the like during high temperature operational conditions, high temperature testing conditions, such as HTRB testing, TC testing, stress testing, and/or the like.

In particular aspects, the h-BN particles may be first treated with a hydrogen peroxide (H₂O₂) solution in an ultrasonic bath at 50-60 degrees C. for a certain time, for example 1-24 hours. The hydroxyl (OH) functionalized h-BN particles may then be filtered, rinsed and completely dried, for example at 60 degrees C. for 24 hours in oven.

However, other Hydroxylation process can be implemented through other methods. For example, a Hydroxylation process such as high temperature treatment, for example at 800 degrees C., stirring, sonicating, and/or the like in different acids. For example, a nitric acid HNO₃, a piranha solution, which may be a mixture of sulfuric acid H₂SO₄ and/or H₂O₂, and/or the like. The hydroxylated h-BN particles may then be filtered and dispersed in an anhydrous solvent, for example ethyl acetate and/or the like. Thereafter, treated with different self-assembled monolayer (SAM) precursors, such as isocyanate precursors, such as triphenylmethanetriisocyanate, while stirred under the purge of nitrogen gas, argon gas, and/or the like for a period of time, such as 5-60 minutes. The fully SAM-functionalized particles may then be mixed, such as with 1%-90% by weight of the h-BN filler, with a polymer, such as an epoxy, a fluoropolymer, and/or the like, or a precursor, such as a polyamic acid and/or the like, while being stirred for 1-24 hours.

Implementations of the disclosed hybrid composite in view of the different failure types such as high operational temperature, TC testing, HTRB testing, stress testing, and/or the like of discrete power packages as well as lower efficacity of using a number of commercially available die-coat materials, which are mainly based on polyimide only, confirm that the disclosed approach could prevent or significantly mitigate such failures.

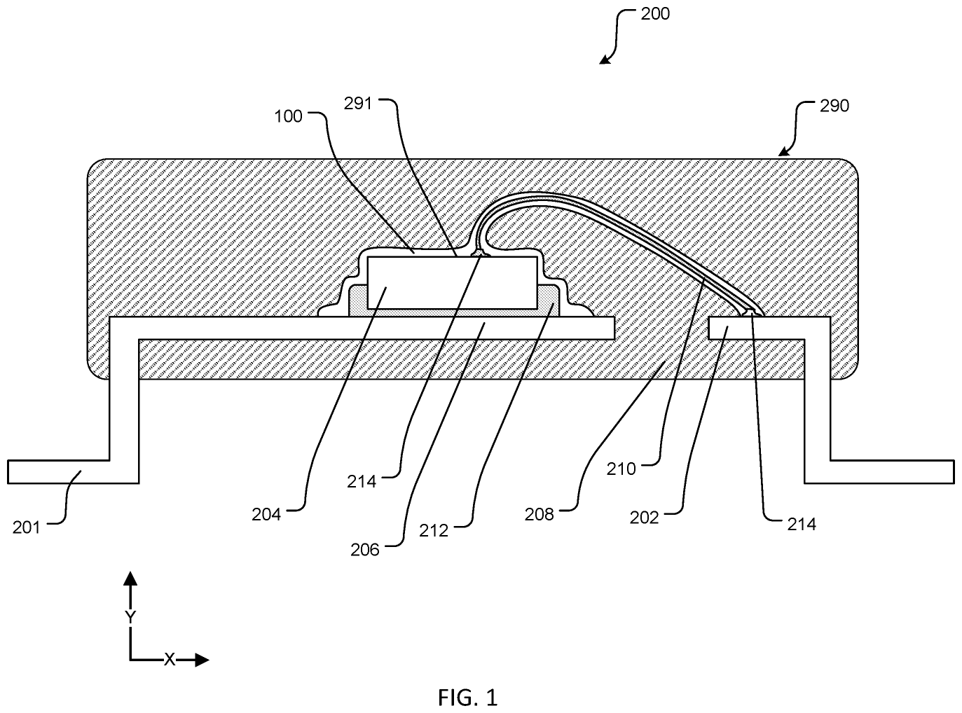

FIG. 1 illustrates a cross-sectional view of a device having device parts with a hybrid composite coating material arranged thereon according to aspects of the disclosure.

In particular, FIG. 1 illustrates a device 200 having device parts 290 with a composite coating material 100 arranged thereon according to aspects of the disclosure. In aspects, the device 200 may include the device parts 290 and the composite coating material 100 may be arranged on one or more of the device parts 290. Further, the device 200 may include a molding compound 208 arranged on and/or around one or more of the device parts 290 having the composite coating material 100 coated thereon; and the device 200 may include the molding compound 208 arranged on one or more of the device parts 290 implemented without the composite coating material 100 coated thereon. Additionally, one or more the device parts 290 may only be partially covered by the molding compound 208.

In aspects the device 200 and/or the device parts 290 may be one or more of a first lead 201, a second lead 202, at least one device component 204, a mount 206, at least one interconnect 210, a component attach 212, at least one connection 214, and/or the like.

As illustrated in FIG. 1, the composite coating material 100 may be at least partially arranged on the at least one device component 204, the mount 206, the at least one interconnect 210, the component attach 212, the at least one connection 214, and/or the like.

In other aspects, the composite coating material 100 may be arranged on fewer components of the device 200. In other aspects, the composite coating material 100 may be arranged on other components of the device 200. In other aspects, the composite coating material 100 may be arranged on additional components of the device 200.

In aspects, the composite coating material 100 may be arranged partially on a single surface of one or more of the device parts 290, the composite coating material 100 may be arranged partially on multiple surfaces of one or more of the device parts 290, the composite coating material 100 may be arranged partially on all exposed surfaces of one or more of the device parts 290, the composite coating material 100 may be arranged partially on all surfaces of one or more of the device parts 290, and/or the like. In this regard, an exposed surface of one or more of the device parts 290 may be a surface that does not include another one of the device parts 290 attached thereto. For example, an upper surface of the at least one device component 204 may be an exposed surface 291 with the exception of a portion of the upper surface where the at least one connection 214 and/or the at least one interconnect 210 are attached and accordingly the exposed surface 291 of the at least one device component 204 may include the composite coating material 100; and the portion of the upper surface where the at least one connection 214 and/or the at least one interconnect 210 are attached may not include the composite coating material 100. As an another example, a lower surface of the at least one device component 204 may be attached to the component attach 212 and accordingly may not be an exposed surface and accordingly will not include the composite coating material 100.

In aspects, the composite coating material 100 may be arranged entirely on a single surface of one or more of the device parts 290, the composite coating material 100 may be arranged entirely on multiple surfaces of one or more of the device parts 290, the composite coating material 100 may be arranged entirely on all exposed surfaces of one or more of the device parts 290, the composite coating material 100 may be arranged entirely on all surfaces of one or more of the device parts 290, and/or the like.

In aspects, the composite coating material 100 may be arranged on surfaces of one or more of the device parts 290 that may contact the molding compound 208. In aspects, the composite coating material 100 may be arranged on surfaces of one or more of the device parts 290 that may directly contact the molding compound 208.

In aspects, the composite coating material 100 may include a hybrid composite of a polymer matrix 102 including and/or incorporating ceramic particles 104. In aspects, the ceramic particles 104 may comprise boron-nitride particles, hexagonal boron-nitride (h-BN) particles, and/or the like. In other aspects, the polymer matrix 102 may include particles of SiNx, Aluminum nitride (AlN), Beryllium oxide (BeO), diamond, and/or the like.

The composite coating material 100 may be formulated and/or configured to efficiently reduce failures of the device parts 290 of the device 200 associated with interfacial stress during high temperature operation of the device 200. For example, high temperature operation of the device 200 and/or the device parts 290 such as thermal cycling (TC) testing of the device 200 and/or the device parts 290, high temperature reverse bias (HTRB) testing of the device 200 and/or the device parts 290, and/or the like.

In aspects, the polymer matrix 102 may include a polyimide, a silicon, a fluoropolymer, copolymers of polyimide-silicon, and/or the like. In aspects, the ceramic particles 104 may have 5 nm to 5 μm sized h-BN particles. In aspects, the ceramic particles 104 may have 1 nm to 100 nm, 100 nm to 200 nm, 200 nm to 300 nm, 300 nm to 400 nm, 400 nm to 500 nm, 500 nm to 600 nm, 600 nm to 700 nm, 700 nm to 800 nm, 800 nm to 900 nm, 900 nm to 1 μm, 1 μm to 2 μm, 2 μm to 3 μm, 3 μm to 4 μm, 4 μm to 5 μm, or 5 μm to 6 μm sized h-BN particles. In aspects, the ceramic particles 104 may be configured as filler within the composite coating material 100.

In aspects, the ceramic particles 104 may be utilized in the composite coating material 100 as hexagonal boron-nitride (h-BN) particles as h-BN is a comparatively soft, low-density material in comparison to numerous other ceramic fillers.

Additionally, in aspects, the ceramic particles 104 may be utilized in the composite coating material 100 as hexagonal boron-nitride (h-BN) particles as h-BN also possess a very high in-plane and relatively high out-of-plane thermal conductivity up to 600 W/mK and 30 W/mK, respectively. Moreover, the h-BN within the composite coating material 100 can be formulated and/or configured to dissipate heat in both directions in the device 200 without any or with negligible localized heat that results in minimizing the CTE-mismatch-induced interfacial stress within the within the device parts 290 of the device 200, between the device parts 290 and the molding compound 208, and/or the like, which may be generated during high temperature operation conditions, testing conditions, and/or the like, such as, for example, temperatures exceeding 150 degrees C. In this regard, high temperature operation conditions of the device parts 290 and/or the device 200 are defined as temperatures exceeding 150 degrees C.

In aspects, the ceramic particles 104 of the composite coating material 100 may include h-BN in forms of h-BN nano-particles, h-BN microparticles, h-BN nanotubes (NT), h-BN pallets, and/or the like. Moreover, the composite coating material 100 may be implemented in combination with other fillers, such as, Aluminide, silica, and/or the like.

In aspects, the composite coating material 100 may be deposited on the device parts 290 of the device 200. In particular aspects, the composite coating material 100 may be deposited on the device parts 290 by dispense, inkjet, spray coat, screen print, deposition, dipping, and/or the like.

In particular aspects, the composite coating material 100 may be a dispensed coating on the device parts 290. In this aspect, the composite coating material 100 may be a dispensed coating on the device parts 290 dispensed from a dispensing device dispensing the composite coating material 100 onto one or more the device parts 290.

In particular aspects, the composite coating material 100 may be an inkjet coating on the device parts 290. In this aspect, the composite coating material 100 may be an inkjet coating on the device parts 290 jetted from an inkjet device jetting the composite coating material 100 onto one or more the device parts 290.

In particular aspects, the composite coating material 100 may be a spray coat coating on the device parts 290. In this aspect, the composite coating material 100 may be sprayed on the device parts 290 sprayed from a spray coating device spraying the composite coating material 100 onto one or more the device parts 290.

In particular aspects, the composite coating material 100 may be a screen printed coating on the device parts 290. In this aspect, the composite coating material 100 may be a screen printed coating on the device parts 290 screen printed from a screen printing device screen printing the composite coating material 100 onto one or more the device parts 290.

In aspects, the composite coating material 100 may be a cured coating that is cured after application of the composite coating material 100 on the device parts 290. In aspects, after application of the composite coating material 100 on the device parts 290, the composite coating material 100 may be degassed at 50-100 degrees C. for 30-60 minutes. Further, the composite coating material 100 may be cured at 150-250 degrees C. for 30-60 minutes. Other curing and degassing temperatures and times are contemplated as well depending on the application.

Thereafter, the molding compound 208 may be arranged on, arranged around, formed on, formed around, and/or the like the device parts 290 having the composite coating material 100 coated thereon and the device parts 290 implemented without the composite coating material 100 coated thereon.

In aspects, preparation of the composite coating material 100 may optionally include initial processes for preparation of the ceramic particles 104 utilizing hexagonal boron-nitride (h-BN) particles. In aspects, the ceramic particles 104 utilizing the hexagonal boron-nitride (h-BN) particles as described herein may be mixed with the polymer matrix 102 together with any other fillers to form the composite coating material 100.

In other aspects, the ceramic particles 104 utilizing hexagonal boron-nitride (h-BN) particles may optionally be processed such that the ceramic particles 104 may have a surface functionalization of the hBN particles. Thereafter, the ceramic particles 104 may be processed by grafting the ceramic particles 104 to a polymer, such as a monomer, an oligomer, the polymer matrix 102, and/or the like, which results in a more uniform distribution of the ceramic particles 104 within the composite coating material 100. Accordingly, in aspects the composite coating material 100 may include the ceramic particles 104 utilizing the hexagonal boron-nitride (h-BN) particles with surface functionalization. Further, in aspects the composite coating material 100 may include the ceramic particles 104 grafted to the polymer matrix 102. Additionally, in aspects the composite coating material 100 may include the hexagonal boron-nitride (h-BN) particles with surface functionalization grafted to the polymer matrix 102.

In aspects, a thin layer of the grafted h-BN hybrid composite implementation of the composite coating material 100 may be capable of uniformly distributing the interfacial thermomechanical stress, such as posed by the molding compound 208, as well as the heat across the coated area of the device parts 290 and may efficiently prevent or significantly mitigate failures of the device parts 290 such as ratcheting-induced metal delamination, ratcheting-induced metal deformation, passivation layer cracking, SiNx passivation layer cracking, and/or the like during high temperature operational conditions of the device 200, high temperature testing conditions of the device 200, such as HTRB testing, TC testing, stress testing, and/or the like.

In particular aspects, preparation of the composite coating material 100 may optionally include certain processes. For example, the h-BN particles may be first treated with a hydrogen peroxide (H₂O₂) solution in an ultrasonic bath at 50-60 degrees C. for a certain time, for example 1-24 hours. The hydroxyl (OH) functionalized h-BN particles may then be filtered with a filtering device. Thereafter, the filtered h-BN particles may be rinsed and completely dried, for example at 60 degrees C. for 24 hours in oven. Other temperatures and times are contemplated as well depending on the application.

However, preparation of the composite coating material 100 may optionally include other Hydroxylation processes that may be implemented through other methods. For example, preparation of the composite coating material 100 may optionally include a Hydroxylation process such as high temperature treatment, for example at 800 degrees C., stirring, sonicating, and/or the like in different acids. For example, a nitric acid HNO₃, a piranha solution, which may be a mixture of sulfuric acid H₂SO₄ and/or H₂O₂, and/or the like. The hydroxylated h-BN particles may then be filtered and dispersed in an anhydrous solvent, for example ethyl acetate and/or the like. Thereafter, treated with different self-assembled monolayer (SAM) precursors, such as isocyanate precursors, such as triphenylmethanetriisocyanate, while stirred under the purge of nitrogen gas, argon gas, and/or the like for a period of time, such as 5-60 minutes. The fully SAM-functionalized particles may then be mixed, such as with 1%-90%, 1%-10%, 10%-20%, 20%-30%, 30%-40%, 40%-50%, 50%-60%, 60%-70%, 70%-80%, or 80%-90% by weight of the h-BN filler, with a polymer, such as an epoxy, a fluoropolymer, and/or the like, or a precursor, such as a polyamic acid or the like, while being stirred for 1-24 hours.

In aspects, the composite coating material 100 may be configured on one or more of the device parts 290 of the device 200 as a shielding material. In particular, the composite coating material 100 may provide shielding from neutrons, cosmetic rays, and/or the like. Accordingly, the composite coating material 100 may provide certain benefits for implementation of the device 200 in aerospace applications. Moreover, the composite coating material 100 may provide electromagnetic interference (EMI) shielding.

Implementations of the disclosed hybrid composite in view of the different failure types such as high operational temperature, TC testing, HTRB testing, stress testing, and/or the like of discrete power packages as well as lower efficacity of using a number of commercially available die-coat materials, which are mainly based on polyimide only, confirm that the disclosed approach could prevent or significantly mitigate such failures.

With reference to FIG. 1, the composite coating material 100 may cover the at least one device component 204, the composite coating material 100 may partially cover the mount 206, the composite coating material 100 may cover the component attach 212, the composite coating material 100 may cover the at least one interconnect 210, the composite coating material 100 may cover the component attach 212, and/or the composite coating material 100 may cover the at least one connection 214.

In aspects, the composite coating material 100 may be arranged on an upper lateral surface of the at least one device component 204, the upper lateral surface being a surface extending along the x-axis as illustrated in FIG. 1. In aspects the composite coating material 100 may be arranged on at least one vertical surface of the at least one device component 204, the at least one vertical surface being a surface extending along the y-axis as illustrated in FIG. 1. The at least one vertical surface being a surface connected to the upper lateral surface of the at least one device component 204. In aspects, the composite coating material 100 may be arranged on at least one side surface of the at least one device component 204, the at least one side surface being a surface connected to the upper lateral surface of the at least one device component 204. In aspects, the composite coating material 100 may completely cover the upper lateral surface of the at least one device component 204, the at least one vertical surface of the at least one device component 204, and the at least one side surface of the at least one device component 204. In aspects, the composite coating material 100 may completely cover exposed portions of the upper lateral surface of the at least one device component 204, the at least one vertical surface of the at least one device component 204, and the at least one side surface of the at least one device component 204. In aspects, the composite coating material 100 may completely cover portions of the upper lateral surface of the at least one device component 204, the at least one vertical surface of the at least one device component 204, and the at least one side surface of the at least one device component 204 adjacent the molding compound 208. In aspects, the composite coating material 100 may partially cover the upper lateral surface of the at least one device component 204, the at least one vertical surface of the at least one device component 204, and the at least one side surface of the at least one device component 204.

In aspects, the composite coating material 100 may be arranged on an upper lateral surface of the component attach 212, the upper lateral surface being a surface extending along the x-axis as illustrated in FIG. 1. In aspects the composite coating material 100 may be arranged on at least one vertical surface of the component attach 212, the at least one vertical surface being a surface extending along the y-axis as illustrated in FIG. 1. The at least one vertical surface being a surface connected to the upper lateral surface of the component attach 212. In aspects, the composite coating material 100 may be arranged on at least one side surface of the component attach 212, the at least one side surface being a surface connected to the upper lateral surface of the component attach 212. In aspects, the composite coating material 100 may completely cover the upper lateral surface of the component attach 212, the at least one vertical surface of the component attach 212, and the at least one side surface of the component attach 212. In aspects, the composite coating material 100 may completely cover exposed portions of the upper lateral surface of the component attach 212, the at least one vertical surface of the component attach 212, and the at least one side surface of the component attach 212. In aspects, the composite coating material 100 may completely cover portions of the upper lateral surface of the component attach 212, the at least one vertical surface of the component attach 212, and the at least one side surface of the component attach 212 adjacent the molding compound 208. In aspects, the composite coating material 100 may partially cover the upper lateral surface of the component attach 212, the at least one vertical surface of the component attach 212, and the at least one side surface of the component attach 212.

The first lead 201 and/or the second lead 202 may be configured as one or more leadframes, terminals, input pins, output pins and/or the like. The first lead 201 and/or the second lead 202 may comprise a metallic material such as copper, gold, nickel, palladium, silver, and the like, and combinations thereof. A construction of the first lead 201 and/or the second lead 202 may be the same or may be different. The first lead 201 and/or the second lead 202 may comprise any shape, location, arrangement, and/or the like. The arrangements as illustrated in the Figures, are merely exemplary.

The at least one device component 204 may be one or more active devices, passive devices, dies, chips, transistors, and/or the like. In aspects, the at least one device component 204 may be implemented as one or more of the power semiconductor devices, a wide band-gap semiconductor device, an ultra-wideband device, a GaN based device, a LDMOS (Laterally-Diffused Metal-Oxide Semiconductor) device, a Metal Semiconductor Field-Effect Transistor (MESFET), a Metal Oxide Field Effect Transistor (MOSFET), a power MOSFET, a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a diode, a power Schottky diode, a gate-controlled thyristor, a Metal Insulator Semiconductor Field Effect Transistor (MISFET), and/or the like. The at least one device component 204 may include a semiconductor layer structure that is formed using, for example, silicon and/or wide bandgap semiconductor materials such as silicon carbide and/or gallium nitride-based and/or aluminum nitride-based semiconductor systems (e.g., GaN, AlGaN, InGaN, AlN, etc.). Other wide bandgap materials may be used such as devices formed in other Group III-V semiconductor systems or in Group II-VI semiconductor systems.

A power semiconductor device may refer to devices that include one or more power semiconductor die that are designed to carry large currents and/or that are capable of blocking high voltages. Herein, a power semiconductor die refers to a semiconductor die that during normal operation can pass at least 1 Amp of current and/or block at least 100 volts during reverse blocking operation. Power semiconductor die may be fabricated from wide bandgap semiconductor materials, such as silicon carbide (“SiC”) or gallium nitride (“GaN”) based semiconductor materials. A wide variety of power semiconductor die are known in the art, including, for example, power Metal Oxide Semiconductor Field Effect Transistors (“MOSFETs”), power insulated gate bipolar junction transistors (“IGBTs”), power Schottky diodes, and/or the like. Power semiconductor die are often packaged to provide a packaged power semiconductor device.

A power MOSFET may be used power semiconductor die. A power MOSFET may be a three terminal device that has gate, drain and source terminals and a semiconductor layer structure that is often referred to as a semiconductor body. A source region and a drain region that are separated by a channel region are formed in the semiconductor body, and a gate electrode (which may act as the gate terminal or be electrically connected to the gate terminal) is disposed adjacent the channel region. The MOSFET may be turned on (to conduct current through the channel region between the source region and drain regions) by applying a bias voltage to the gate electrode, and may be turned off (to block current flow through the channel region) by removing the bias voltage (or reducing the bias voltage below a threshold level).

Aspects of the disclosure may implement the device 200 as a discrete packaged power semiconductor device or multichip power packaged power semiconductor devices. A discrete power packaged power semiconductor device may include a single power semiconductor die, such as a packaged MOSFET, Schottky diode, IGBT and/or the like. The multichip power packaged power semiconductor devices refer to power semiconductor modules that include two or more power semiconductor dies that are provided (and typically interconnected) within a common package.

The mount 206 may be implemented as a metal submount, a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The mount 206 may include an insulating material, a dielectric material, and/or the like.

In aspects, the mount 206 may be implemented as a power substrate that includes a ceramic substrate. In aspects, the power substrate may include a lower metal cladding layer formed on a lower side of the ceramic substrate, and an upper metal cladding layer may be formed on the upper side of the ceramic substrate. As used herein, the term “power substrate” refers to a dielectric substrate that has a metal cladding layer on both sides thereof. In aspects, the power substrate may be an Active Metal Brazed (“AMB”) power substrate, which includes first and second metal braze layers that may be used to bond first and second metal cladding layers, respectively, to the ceramic substrate. In aspects, the power substrate may be a Substrate (or, more typically, a Direct Bonded Copper or “DBC” power substrate, as the metal cladding layers may typically be copper layers).

The molding compound 208 may substantially surround the device parts 290 and may be formed of a plastic or a plastic polymer compound, which may be injection molded around the second lead 202, the at least one device component 204, the mount 206, the at least one interconnect 210, the component attach 212, the at least one connection 214, the device parts 290, and/or the like, thereby providing protection from the outside environment. The molding compound 208 may be formed of a plastic, a mold compound, a plastic compound, a polymer, a polymer compound, a plastic polymer compound, an epoxy molding compound, and/or the like. The molding compound 208 may be injection molded, transfer molded, compression molded, and/or the like around the second lead 202, the at least one device component 204, the mount 206, the at least one interconnect 210, the component attach 212, the at least one connection 214, the device parts 290, and/or the like, thereby providing protection for the device 200, from the outside environment.

The at least one interconnect 210 may be implemented as one or more wires, wire bonds, leads, vias, edge platings, circuit traces, tracks, clips, and/or the like. In one aspect, the at least one interconnect 210 may utilize the same type of connection. In one aspect, the at least one interconnect 210 may utilize different types of connections.

In aspects, the component attach 212 may include implementations of adhesive, soldering, sintering, eutectic bonding, ultrasonically welding, and/or the like as described herein. In aspects, the component attach 212 may be configured to transfer heat to and from the at least one device component 204 and the mount 206.

The at least one connection 214 may utilize ball bonding, wedge bonding, compliant bonding, ribbon bonding, metal clip attach, and/or the like. In one aspect, the at least one connection 214 may utilize the same type of connection. In one aspect, the at least one interconnect 210 may utilize different types of connections. In aspects, the at least one connection 214 may include implementations of adhesive, soldering, sintering, eutectic bonding, ultrasonically welding, and/or the like as described herein.

In aspects, the device 200 may be implemented as a packaged power device, a packaged power semiconductor device, a packaged MOSFET device, a package diode device, a power module, a RF package, a RF amplifier package, a RF power amplifier package, a RF power transistor package, a RF power amplifier transistor package, a component such as a General-Purpose Broadband component, a Telecom component, a L-Band component, a S-Band component, a X-Band component, a C-Band component, a Ku-Band component, a Satellite Communications component, a Doherty configuration, and/or the like.

Additionally, aspects of the composite coating material 100 and/or the device 200 as illustrated in FIG. 1 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 1.

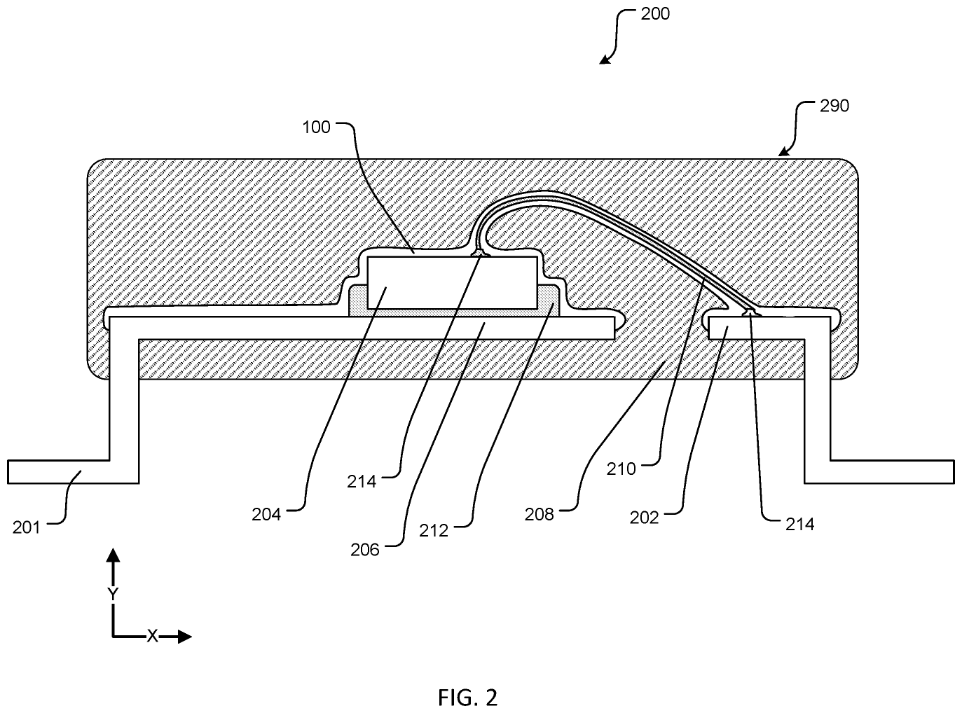

FIG. 2 illustrates a cross-sectional view of a device having different device parts with a hybrid composite coating material arranged thereon according to aspects of the disclosure.

In particular, FIG. 2 illustrates a device 200 having different device parts 290 with a composite coating material 100 arranged thereon according to aspects of the disclosure. In this regard, aspects of the composite coating material 100 and/or the device 200 as illustrated in FIG. 2 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 2.

As illustrated in FIG. 2, the composite coating material 100 may be arranged on one or more of the first lead 201, the second lead 202, the at least one device component 204, the mount 206, the at least one interconnect 210, the component attach 212, the at least one connection 214, and/or the like. In particular aspects, the composite coating material 100 may be arranged on upper surface of the mount 206 and an upper surface of the second lead 202.

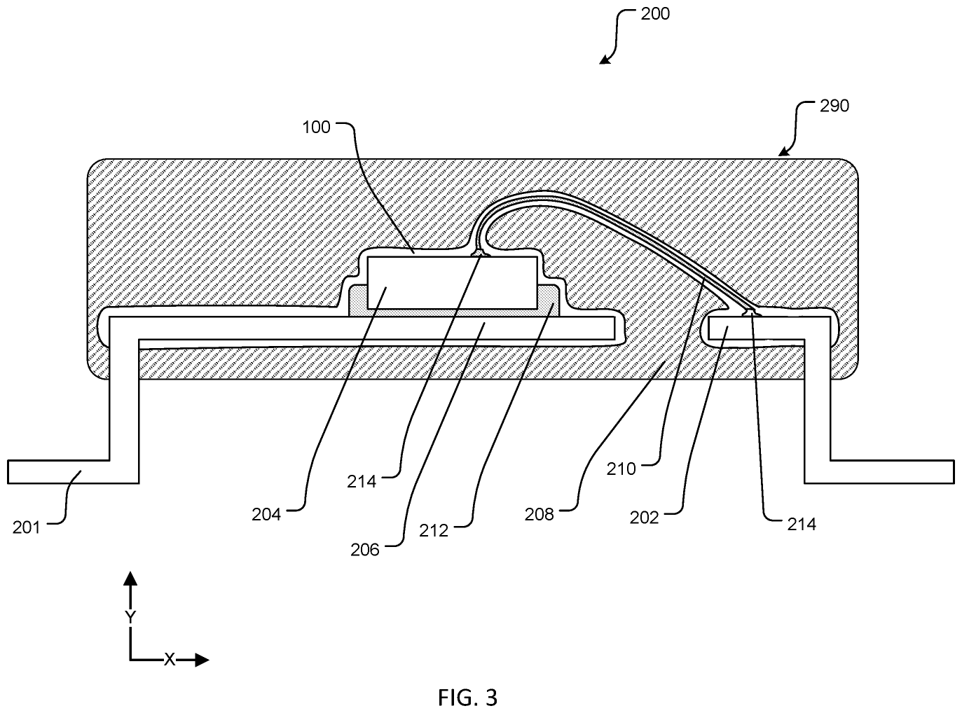

FIG. 3 illustrates a cross-sectional view of a device having different device parts with a hybrid composite coating material arranged thereon according to aspects of the disclosure.

In particular, FIG. 3 illustrates a device 200 having different device parts 290 with a composite coating material 100 arranged thereon according to aspects of the disclosure. In this regard, aspects of the composite coating material 100 and/or the device 200 as illustrated in FIG. 3 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 3.

As illustrated in FIG. 3, the composite coating material 100 may be arranged on one or more of the first lead 201, the second lead 202, the at least one device component 204, the mount 206, the at least one interconnect 210, the component attach 212, the at least one connection 214, and/or the like. In particular aspects, the composite coating material 100 may be arranged on an upper surface of the mount 206 and an upper surface of the second lead 202. In particular aspects, the composite coating material 100 may be arranged on a lower surface of the mount 206 and a lower surface of the second lead 202.

In aspects, the composite coating material 100 may be arranged on an upper lateral surface of the mount 206, the upper lateral surface being a surface extending along the x-axis as illustrated in FIG. 3. In aspects the composite coating material 100 may be arranged on at least one vertical surface of the mount 206, the at least one vertical surface being a surface extending along the y-axis as illustrated in FIG. 3. The at least one vertical surface being a surface connected to the upper lateral surface of the mount 206. In aspects, the composite coating material 100 may be arranged on at least one side surface of the mount 206, the at least one side surface being a surface connected to the upper lateral surface of the mount 206. In aspects, the composite coating material 100 may completely cover the upper lateral surface of the mount 206, the at least one vertical surface of the mount 206, and the at least one side surface of the mount 206. In aspects, the composite coating material 100 may completely cover exposed portions of the upper lateral surface of the mount 206, the at least one vertical surface of the mount 206, and the at least one side surface of the mount 206. In aspects, the composite coating material 100 may completely cover portions of the upper lateral surface of the mount 206, the at least one vertical surface of the mount 206, and the at least one side surface of the mount 206 adjacent the molding compound 208. In aspects, the composite coating material 100 may partially cover the upper lateral surface of the mount 206, the at least one vertical surface of the mount 206, and the at least one side surface of the mount 206.

In aspects, the composite coating material 100 may be arranged on an upper lateral surface of the second lead 202, the upper lateral surface being a surface extending along the x-axis as illustrated in FIG. 3. In aspects the composite coating material 100 may be arranged on at least one vertical surface of the second lead 202, the at least one vertical surface being a surface extending along the y-axis as illustrated in FIG. 3. The at least one vertical surface being a surface connected to the upper lateral surface of the second lead 202. In aspects, the composite coating material 100 may be arranged on at least one side surface of the second lead 202, the at least one side surface being a surface connected to the upper lateral surface of the second lead 202. In aspects, the composite coating material 100 may completely cover the upper lateral surface of the second lead 202, the at least one vertical surface of the second lead 202, and the at least one side surface of the second lead 202. In aspects, the composite coating material 100 may completely cover exposed portions of the upper lateral surface of the second lead 202, the at least one vertical surface of the second lead 202, and the at least one side surface of the second lead 202. In aspects, the composite coating material 100 may completely cover portions of the upper lateral surface of the second lead 202, the at least one vertical surface of the second lead 202, and the at least one side surface of the second lead 202 adjacent the molding compound 208. In aspects, the composite coating material 100 may partially cover the upper lateral surface of the second lead 202, the at least one vertical surface of the second lead 202, and the at least one side surface of the second lead 202.

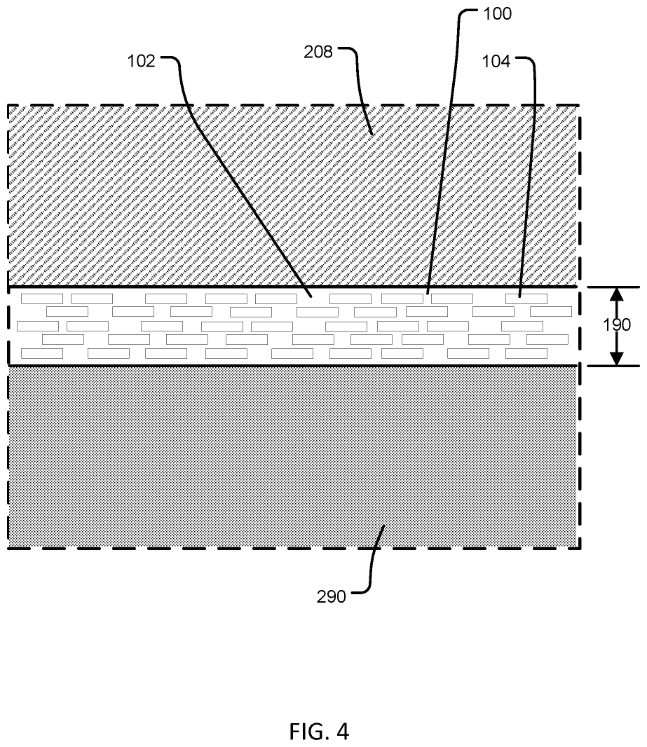

FIG. 4 illustrates a cross-sectional view of the composite coating material arranged on the device parts of the device according to aspects of the disclosure.

In particular, FIG. 4 illustrates a cross-sectional view of the composite coating material 100 arranged on one or more of the device parts 290 of the device 200 according to aspects of the disclosure. In this regard, aspects of the composite coating material 100 and/or the device 200 as illustrated in FIG. 4 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 4.

As illustrated in FIG. 4, the composite coating material 100 may include the polymer matrix 102 and the ceramic particles 104. Further, the composite coating material 100 may be arranged on a surface of one or more of the device parts 290 of the device 200. In aspects, the composite coating material 100 may be arranged directly on a surface of one or more of the device parts 290 of the device 200. In aspects, the composite coating material 100 may be arranged on a surface of one or more of the device parts 290 of the device 200 with intervening layers of material therebetween.

In aspects, the molding compound 208 may be arranged on a surface of the composite coating material 100. In aspects, the molding compound 208 may be arranged directly on a surface of the composite coating material 100. In aspects, the molding compound 208 may be arranged on a surface of the composite coating material 100 with intervening layers of material therebetween.

In aspects, the composite coating material 100 may have a thickness 190. In certain implementations of the device parts 290 of the device 200, the thickness 190 of the composite coating material 100 may be 2 to 30 μm, 2 to 5 μm, 5 to 10 μm, 10 to 20 μm, or 20 to 30 μm. In certain implementations of the device parts 290 of the device 200, the thickness 190 of the composite coating material 100 may be less than 10 μm, less than 20 μm, or less than 30 μm. In certain implementations of the device parts 290 of the device 200, the thickness 190 of the composite coating material 100 may be more than 10 μm, more than 20 μm, more than 30 μm, more than 40 μm, more than 50 μm, or more than 60 μm.

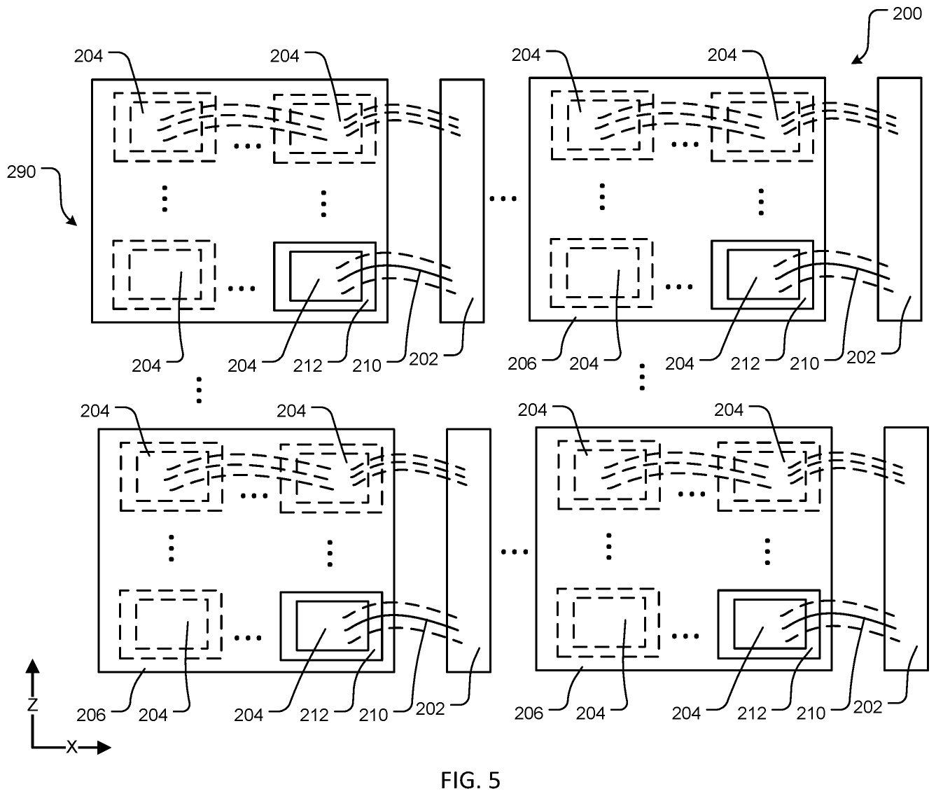

FIG. 5 illustrates a top view of the device implementing the device parts according to aspects of the disclosure.

In particular, FIG. 5 illustrates a top view of the device 200 implementing the device parts 290 according to aspects of the disclosure. In this regard, aspects of the composite coating material 100 and/or the device 200 as illustrated in FIG. 5 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 5.

FIG. 5 illustrates portions of the device 200 without the molding compound 208 and the composite coating material 100 for ease of illustration. In this regard, FIG. 5 illustrates that the device 200 may include any number of the at least one device component 204, any number of the at least one interconnect 210, and/or the like. More specifically, there may be any number of the at least one device component 204 extending laterally across the mount 206 along the x-axis; and there may be any number of the at least one device component 204 extending longitudinally across the mount 206 along the z-axis. Additionally, the various implementations of the at least one device component 204 may be different; and/or some of the various implementations of the at least one device component 204 may have the same configuration.

Likewise, there may be any number of the at least one interconnect 210 implemented in the device parts 290 of the device 200. Additionally, the various implementations of the at least one interconnect 210 may be different; and/or some of the various implementations of the at least one interconnect 210 may have the same configuration.

In this regard, aspects of the device 200 implementing the composite coating material 100 on one or more of the device parts 290 may include any number of the first lead 201, any number of the second lead 202, any number of the mount 206, any number the at least one interconnect 210, and/or the like. Moreover, any one or more of the device parts 290 may include the composite coating material 100; and any one or more of the device parts 290 of the device 200 may not include the composite coating material 100.

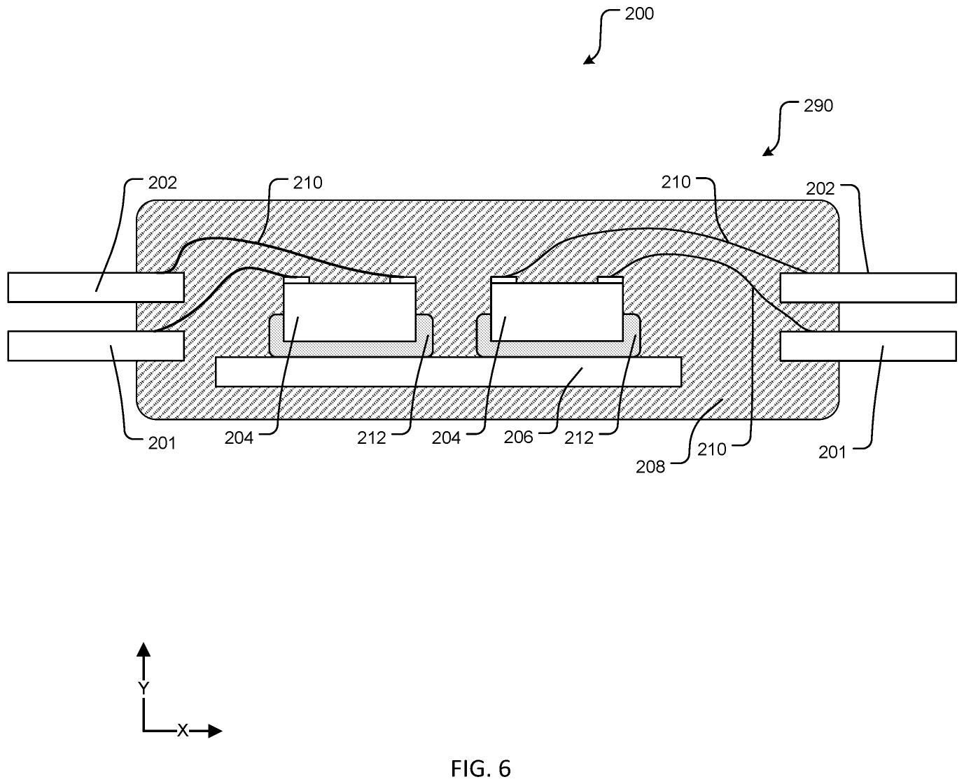

FIG. 6 illustrates a cross-sectional view of the device implementing the device parts according to aspects of the disclosure.

In particular, FIG. 6 illustrates a cross-sectional view of the device 200 implementing the device parts 290 according to aspects of the disclosure. In this regard, aspects of the composite coating material 100 and/or the device 200 as illustrated in FIG. 6 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 6.

FIG. 6 illustrates portions of the device 200 without the composite coating material 100 for ease of illustration. In this regard, FIG. 6 illustrates that the device 200 may have a different configuration, number, and/or arrangement of the first lead 201, the second lead 202, the at least one device component 204, the at least one interconnect 210, and/or the like.

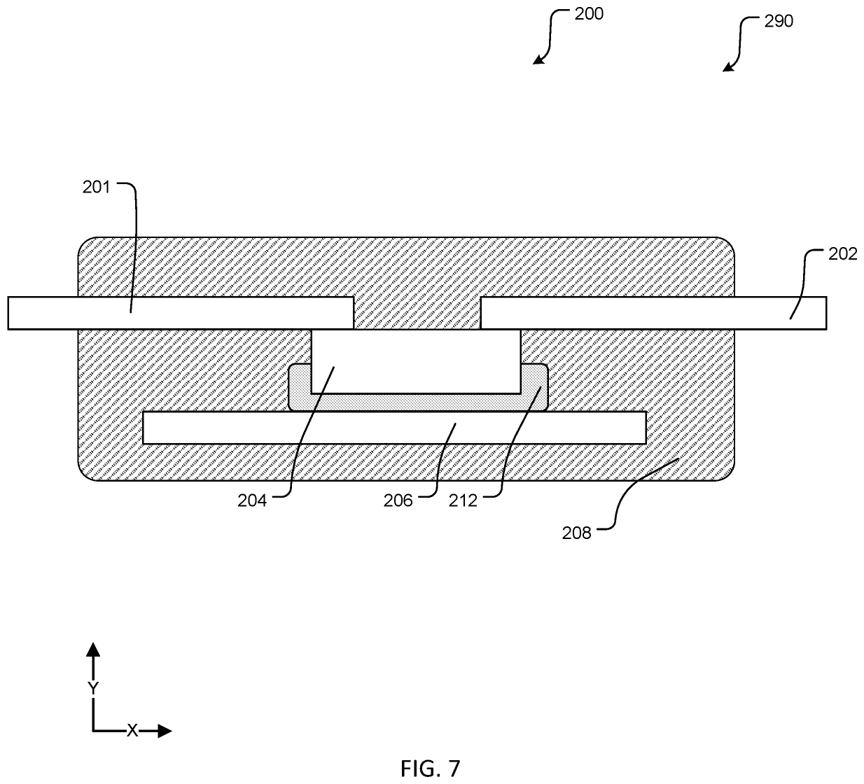

FIG. 7 illustrates a cross-sectional view of the device implementing the device parts according to aspects of the disclosure.

In particular, FIG. 7 illustrates a cross-sectional view of the device 200 implementing the device parts 290 according to aspects of the disclosure. In this regard, aspects of the composite coating material 100 and/or the device 200 as illustrated in FIG. 7 may optionally be implemented in any other aspects of the composite coating material 100 and/or the device 200 as described herein. Moreover, aspects of the composite coating material 100 and/or the device 200 may optionally implement other aspects of the composite coating material 100 and/or the device 200 as described herein in the aspects of the composite coating material 100 and/or the device 200 illustrated and described with respect to FIG. 7.

FIG. 7 illustrates portions of the device 200 without the composite coating material 100 for ease of illustration. In this regard, FIG. 7 illustrates that the device 200 may have a different configuration, number, and/or arrangement of the first lead 201, the second lead 202, the at least one device component 204, and/or the like.

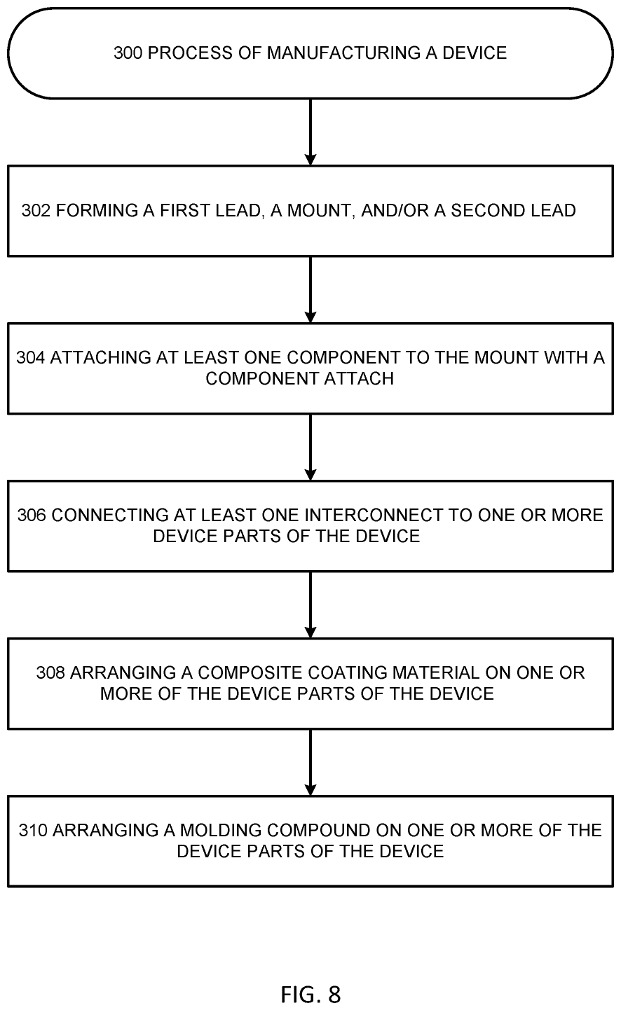

FIG. 8 illustrates a process of manufacturing a device according to aspects of the disclosure.

In particular, FIG. 8 illustrates a process of manufacturing a device 300 according to aspects of the disclosure. In particular, it should be noted that the process of manufacturing a device 300 is merely exemplary and may be modified consistent with the various aspects disclosed herein. Moreover, the process of manufacturing a device 300 of the disclosure may include a process of manufacturing the device 200. It should be noted that the process of manufacturing a device 300 may be performed in a different order consistent with the aspects described above. Moreover, the process of manufacturing a device 300 may be modified to have more or fewer process steps consistent with the various aspects disclosed herein.

The process of manufacturing a device 300 of the disclosure may include forming a first lead, a mount, and/or a second lead 302. In this regard, the forming a first lead, a mount, and/or a second lead 302 may include any one or more materials, structures, arrangements, processes, and/or the like as described herein. Moreover, one or more proceeding or subsequent processes may also be implemented with respect to the forming a first lead, a mount, and/or a second lead 302 consistent with the disclosure.

In particular aspects, the forming a first lead, a mount, and/or a second lead 302 may include forming the first lead 201, the mount 206, the second lead 202, and/or other components of the device 200 as described herein.

The process of manufacturing a device 300 of the disclosure may include attaching at least one component to the mount with a component attach 304. In this regard, the attaching at least one component to the mount with a component attach 304 may include any one or more materials, structures, arrangements, processes, and/or the like as described herein. Moreover, one or more proceeding or subsequent processes may also be implemented with respect to the attaching at least one component to the mount with a component attach 304 consistent with the disclosure.

In particular aspects, the attaching at least one component to the mount with a component attach 304 may include attaching the at least one device component 204 to the mount 206 with the component attach 212 as described herein.

The process of manufacturing a device 300 of the disclosure may include connecting at least one interconnect to one or more device parts of the device 306. In this regard, the connecting at least one interconnect to one or more device parts of the device 306 may include any one or more materials, structures, arrangements, processes, and/or the like as described herein. Moreover, one or more proceeding or subsequent processes may also be implemented with respect to the connecting at least one interconnect to one or more device parts of the device 306 consistent with the disclosure.

In particular aspects, the connecting at least one interconnect to one or more device parts of the device 306 may include connecting the at least one interconnect 210 to one or more of the device parts 290 of the device 200 as described herein.

The process of manufacturing a device 300 of the disclosure may include arranging a composite coating material on one or more of the device parts of the device 308. In this regard, the arranging a composite coating material on one or more of the device parts of the device 308 may include any one or more materials, structures, arrangements, processes, and/or the like as described herein. Moreover, one or more proceeding or subsequent processes may also be implemented with respect to the arranging a composite coating material on one or more of the device parts of the device 308 consistent with the disclosure.

In particular aspects, the arranging a composite coating material on one or more of the device parts of the device 308 may include arranging the composite coating material 100 on one or more of the device parts 290 of the device 200 as described herein. In aspects, the arranging a composite coating material on one or more of the device parts of the device 308 may include depositing the composite coating material 100 on the device parts 290 of the device 200. In particular aspects, the composite coating material 100 may be deposited on the device parts 290 by dispense, inkjet, spray coat, screen print, deposition, dipping, and/or the like.

In aspects, the arranging a composite coating material on one or more of the device parts of the device 308 may include curing the composite coating material 100 after application of the composite coating material 100 on the device parts 290. In aspects, after application of the composite coating material 100 on the device parts 290, the composite coating material 100 may be degassed at 50-100 degrees C. for 30-60 minutes. Further, the composite coating material 100 may be cured at 150-250 degrees C. for 30-60 minutes. Other curing and degassing temperatures and times are contemplated as well depending on the application.

In aspects, the arranging a composite coating material on one or more of the device parts of the device 308 may include preparing the composite coating material 100 that may optionally include initial processes for preparation of the ceramic particles 104 utilizing hexagonal boron-nitride (h-BN) particles. In aspects, the ceramic particles 104 utilizing the hexagonal boron-nitride (h-BN) particles as described herein may be mixed with the polymer matrix 102 together with any other fillers to form the composite coating material 100.

In other aspects, the arranging a composite coating material on one or more of the device parts of the device 308 may include processing the ceramic particles 104 utilizing hexagonal boron-nitride (h-BN) particles such that the ceramic particles 104 may have a surface functionalization of the hBN particles. Thereafter, the ceramic particles 104 may be processed by grafting the ceramic particles 104 to a polymer, such as a monomer, an oligomer, the polymer matrix 102, and/or the like, which results in a more uniform distribution of the ceramic particles 104 within the composite coating material 100. Accordingly, in aspects the composite coating material 100 may include the ceramic particles 104 utilizing the hexagonal boron-nitride (h-BN) particles with surface functionalization. Further, in aspects the composite coating material 100 may include the ceramic particles 104 grafted to the polymer matrix 102. Additionally, in aspects the composite coating material 100 may include the hexagonal boron-nitride (h-BN) particles with surface functionalization grafted to the polymer matrix 102.

The process of manufacturing a device 300 of the disclosure may include arranging a molding compound on one or more of the device parts of the device 310. In this regard, the arranging a molding compound on one or more of the device parts of the device 310 may include any one or more materials, structures, arrangements, processes, and/or the like as described herein. Moreover, one or more proceeding or subsequent processes may also be implemented with respect to the arranging a molding compound on one or more of the device parts of the device 310 consistent with the disclosure.

In particular aspects, the arranging a molding compound on one or more of the device parts of the device 310 may include arranging the molding compound 208 on one or more of the device parts 290 of the device 200 as described herein. In aspects, the arranging a molding compound on one or more of the device parts of the device 310 may include forming the molding compound 208 to substantially surround the device parts 290. The molding compound 208 may be formed of a plastic, a mold compound, a plastic compound, a polymer, a polymer compound, a plastic polymer compound, an epoxy molding compound, and/or the like. The molding compound 208 may be injection molded, transfer molded, compression molded, and/or the like around the second lead 202, the at least one device component 204, the mount 206, the at least one interconnect 210, the component attach 212, the at least one connection 214, the device parts 290, and/or the like, thereby providing protection for the device 200, from the outside environment.

Accordingly, the disclosure has set forth a stress buffer coat material providing improved mitigation of interfacial stress, devices implementing a stress buffer coat material providing improved mitigation of interfacial stress, and/or the like.

The following are a number of nonlimiting EXAMPLES of aspects of the disclosure.

One EXAMPLE: a device includes device parts. The device in addition includes a composite coating material arranged on one or more of the device parts. The device moreover includes a molding compound arranged on and/or around one or more of the device parts. The device also includes where the composite coating material includes a polymer matrix including and/or incorporating ceramic particles.

The above-noted EXAMPLE may further include any one or a combination of more than one of the following EXAMPLES:

The device of the above-noted EXAMPLE where the molding compound is further arranged on one or more of the device parts implemented without the composite coating material coated thereon. The device of the above-noted EXAMPLE where the device parts includes one or more of a first lead, a second lead, at least one device component, a mount, at least one interconnect, a component attach, and/or at least one connection. The device of the above-noted EXAMPLE where the at least one device component includes one or more MOSFETs and/or diodes. The device of the above-noted EXAMPLE where the at least one device component includes one or more active devices, passive devices, dies, chips, and/or transistors. The device of the above-noted EXAMPLE where the at least one interconnect includes one or more wires, wire bonds, and/or leads. The device of the above-noted EXAMPLE where the device parts includes at least one lead frame. The device of the above-noted EXAMPLE where the composite coating material is arranged on all exposed surfaces of one or more of the device parts. The device of the above-noted EXAMPLE where the composite coating material is arranged on surfaces of one or more of the device parts that contact the molding compound. The device of the above-noted EXAMPLE where the composite coating material is formulated and/or configured to reduce failures of the device parts associated with interfacial stress exhibited during high temperature operation of the device. The device of the above-noted EXAMPLE where the polymer matrix includes a polyimide, a silicon, a fluoropolymer, and/or copolymers of a polyimide-silicon. The device of the above-noted EXAMPLE where the ceramic particles includes hexagonal boron-nitride (h-BN) particles; and where the hexagonal boron-nitride (h-BN) particles includes 5 nm to 5 μm sized h-BN particles. The device of the above-noted EXAMPLE where the ceramic particles includes hexagonal boron-nitride (h-BN) particles; and where the hexagonal boron-nitride (h-BN) particles includes a filler within the composite coating material. The device of the above-noted EXAMPLE where the ceramic particles includes hexagonal boron-nitride (h-BN) particles; and where the hexagonal boron-nitride (h-BN) particles includes h-BN in forms of h-BN nano-particles, h-BN microparticles, h-BN nanotubes (NT), and/or h-BN pallets. The device of the above-noted EXAMPLE where the composite coating material includes a dispensed coating on one or more of the device parts. The device of the above-noted EXAMPLE where the composite coating material includes an inkjet coating on one or more of the device parts. The device of the above-noted EXAMPLE where the composite coating material includes a spray coating on one or more of the device parts. The device of the above-noted EXAMPLE where the composite coating material includes a screen printed coating on one or more of the device parts. The device of the above-noted EXAMPLE where the composite coating material includes a cured coating on one or more of the device parts. The device of the above-noted EXAMPLE where the ceramic particles includes hexagonal boron-nitride (h-BN) particles; and where the composite coating material includes a mixture of at least the hexagonal boron-nitride (h-BN) particles and the polymer matrix. The device of the above-noted EXAMPLE where the ceramic particles includes hexagonal boron-nitride (h-BN) particles; and where the composite coating material includes a mixture of at least the hexagonal boron-nitride (h-BN) particles and the polymer matrix together with other fillers. The device of the above-noted EXAMPLE where the ceramic particles includes hexagonal boron-nitride (h-BN) particles; and where the hexagonal boron-nitride (h-BN) particles includes a surface functionalization. The device of the above-noted EXAMPLE where the ceramic particles includes hexagonal boron-nitride (h-BN) particles; and where the hexagonal boron-nitride (h-BN) particles are grafted to the polymer matrix. The device of the above-noted EXAMPLE where the ceramic particles includes hexagonal boron-nitride (h-BN) particles; and where the hexagonal boron-nitride (h-BN) particles includes surface functionalization and the hexagonal boron-nitride (h-BN) particles are grafted to the polymer matrix. The device of the above-noted EXAMPLE where the device includes a package, a power device package, and/or a power module.

One EXAMPLE: a process includes providing device parts. The process in addition includes arranging a composite coating material on one or more of the device parts. The process moreover includes arranging a molding compound on and/or around one or more of the device parts. The process also includes where the composite coating material includes a polymer matrix including and/or incorporating ceramic particles.

The above-noted EXAMPLE may further include any one or a combination of more than one of the following EXAMPLES:

The process of the above-noted EXAMPLE includes arranging the molding compound on one or more of the device parts implemented without the composite coating material coated thereon. The process of the above-noted EXAMPLE where the device parts includes one or more of a first lead, a second lead, at least one device component, a mount, at least one interconnect, a component attach, and/or at least one connection. The process of the above-noted EXAMPLE where the at least one device component includes one or more active devices, passive devices, dies, chips, and/or transistors. The process of the above-noted EXAMPLE where the device parts includes at least one lead frame. The process of the above-noted EXAMPLE where the at least one interconnect includes one or more wires, wire bonds, and/or leads. The process of the above-noted EXAMPLE where the device parts includes at least one lead frame. The process of the above-noted EXAMPLE includes arranging the composite coating material on all exposed surfaces of one or more of the device parts. The process of the above-noted EXAMPLE includes arranging the composite coating material on surfaces of one or more of the device parts that contact the molding compound. The process of the above-noted EXAMPLE where the composite coating material is formulated and/or configured to reduce failures of the device parts associated with interfacial stress exhibited during high temperature operation of the device. The process of the above-noted EXAMPLE where the polymer matrix includes a polyimide, a silicon, a fluoropolymer, and/or copolymers of a polyimide-silicon. The process of the above-noted EXAMPLE where the ceramic particles includes hexagonal boron-nitride (h-BN) particles; and where the hexagonal boron-nitride (h-BN) particles includes 5 nm to 5 μm sized h-BN particles. The process of the above-noted EXAMPLE where the ceramic particles includes hexagonal boron-nitride (h-BN) particles; and where the hexagonal boron-nitride (h-BN) particles includes a filler within the composite coating material. The process of the above-noted EXAMPLE where the ceramic particles includes hexagonal boron-nitride (h-BN) particles; and where the hexagonal boron-nitride (h-BN) particles includes h-BN in forms of h-BN nano-particles, h-BN microparticles, h-BN nanotubes (NT), and/or h-BN pallets. The process of the above-noted EXAMPLE includes dispensing the composite coating material on one or more of the device parts to form a dispensed coating on one or more of the device parts. The process of the above-noted EXAMPLE includes ink jetting the composite coating material on one or more of the device parts to form an inkjet coating on one or more of the device parts. The process of the above-noted EXAMPLE includes spray coating the composite coating material on one or more of the device parts to form a spray coating on one or more of the device parts. The process of the above-noted EXAMPLE includes screen printing the composite coating material on one or more of the device parts to form a screen printed coating on one or more of the device parts. The process of the above-noted EXAMPLE includes curing the composite coating material on one or more of the device parts to form a cured coating on one or more of the device parts. The process of the above-noted EXAMPLE where the ceramic particles includes hexagonal boron-nitride (h-BN) particles; and the process includes formulating the composite coating material by mixing at least the hexagonal boron-nitride (h-BN) particles and the polymer matrix. The process of the above-noted EXAMPLE where the ceramic particles includes hexagonal boron-nitride (h-BN) particles; and the process includes formulating the composite coating material by mixing at least the hexagonal boron-nitride (h-BN) particles and the polymer matrix together with other fillers. The process of the above-noted EXAMPLE where the ceramic particles includes hexagonal boron-nitride (h-BN) particles; and the process includes processing the hexagonal boron-nitride (h-BN) particles to form a surface functionalization. The process of the above-noted EXAMPLE where the ceramic particles includes hexagonal boron-nitride (h-BN) particles; and the process includes grafting the hexagonal boron-nitride (h-BN) particles to the polymer matrix. The process of the above-noted EXAMPLE where the ceramic particles includes hexagonal boron-nitride (h-BN) particles; and the process includes: processing the hexagonal boron-nitride (h-BN) particles to form a surface functionalization; and grafting the hexagonal boron-nitride (h-BN) particles to the polymer matrix. The process of the above-noted EXAMPLE includes implementing the device as a package, a power device package, and/or a power module.

One EXAMPLE: a composite coating material includes ceramic particles. The composite coating material in addition includes a polymer matrix including and/or incorporating the ceramic particles.

The above-noted EXAMPLE may further include any one or a combination of more than one of the following EXAMPLES:

The composite coating material of the above-noted EXAMPLE where the composite coating material is formulated and/or configured to reduce failures of device parts associated with interfacial stress exhibited during high temperature operation. The composite coating material of the above-noted EXAMPLE where the polymer matrix includes a polyimide, a silicon, a fluoropolymer, and/or copolymers of a polyimide-silicon. The composite coating material of the above-noted EXAMPLE where the ceramic particles includes hexagonal boron-nitride (h-BN) particles; and where the hexagonal boron-nitride (h-BN) particles includes 5 nm to 5 μm sized h-BN particles. The composite coating material of the above-noted EXAMPLE where the ceramic particles includes hexagonal boron-nitride (h-BN) particles; and where the hexagonal boron-nitride (h-BN) particles includes a filler within the composite coating material. The composite coating material of the above-noted EXAMPLE where the ceramic particles includes hexagonal boron-nitride (h-BN) particles; and where the hexagonal boron-nitride (h-BN) particles includes h-BN in forms of h-BN nano-particles, h-BN microparticles, h-BN nanotubes (NT), and/or h-BN pallets. The composite coating material of the above-noted EXAMPLE where the composite coating material includes a formulation to form a dispensed coating on one or more device parts. The composite coating material of the above-noted EXAMPLE where the composite coating material includes a formulation to form an inkjet coating on one or more device parts. The composite coating material of the above-noted EXAMPLE where the composite coating material includes a formulation to form a spray coating on one or more device parts. The composite coating material of the above-noted EXAMPLE where the composite coating material includes a formulation to form a screen printed coating on one or more device parts. The composite coating material of the above-noted EXAMPLE where the composite coating material includes a formulation to form a cured coating on one or more device parts. The composite coating material of the above-noted EXAMPLE where the ceramic particles includes hexagonal boron-nitride (h-BN) particles; and where the composite coating material includes a mixture of at least the hexagonal boron-nitride (h-BN) particles and the polymer matrix. The composite coating material of the above-noted EXAMPLE where the ceramic particles includes hexagonal boron-nitride (h-BN) particles; and where the composite coating material includes a mixture of at least the hexagonal boron-nitride (h-BN) particles and the polymer matrix together with other fillers. The composite coating material of the above-noted EXAMPLE where the ceramic particles includes hexagonal boron-nitride (h-BN) particles; and where the hexagonal boron-nitride (h-BN) particles includes a surface functionalization. The composite coating material of the above-noted EXAMPLE where the ceramic particles includes hexagonal boron-nitride (h-BN) particles; and where the hexagonal boron-nitride (h-BN) particles are grafted to the polymer matrix. The composite coating material of the above-noted EXAMPLE where the ceramic particles includes hexagonal boron-nitride (h-BN) particles; and where the hexagonal boron-nitride (h-BN) particles includes surface functionalization and the hexagonal boron-nitride (h-BN) particles are grafted to the polymer matrix.

One EXAMPLE: a process includes providing a polymer matrix. The process in addition includes incorporating ceramic particles into the polymer matrix.

The above-noted EXAMPLE may further include any one or a combination of more than one of the following EXAMPLES:

The process of the above-noted EXAMPLE where the ceramic particles includes hexagonal boron-nitride (h-BN) particles; and the process includes formulating the composite coating material by mixing at least the hexagonal boron-nitride (h-BN) particles and the polymer matrix. The process of the above-noted EXAMPLE where the ceramic particles includes hexagonal boron-nitride (h-BN) particles; and the process includes formulating the composite coating material by mixing at least the hexagonal boron-nitride (h-BN) particles and the polymer matrix together with any other fillers. The process of the above-noted EXAMPLE where the ceramic particles includes hexagonal boron-nitride (h-BN) particles; and the process includes processing the hexagonal boron-nitride (h-BN) particles to form a surface functionalization. The process of the above-noted EXAMPLE where the ceramic particles includes hexagonal boron-nitride (h-BN) particles; and the process includes grafting the hexagonal boron-nitride (h-BN) particles to the polymer matrix. The process of the above-noted EXAMPLE where the ceramic particles includes hexagonal boron-nitride (h-BN) particles; and the process includes: processing the hexagonal boron-nitride (h-BN) particles to form a surface functionalization; and grafting the hexagonal boron-nitride (h-BN) particles to the polymer matrix. The process of the above-noted EXAMPLE includes formulating an/or configuring the composite coating material to reduce failures of device parts associated with interfacial stress exhibited during high temperature operation. The process of the above-noted EXAMPLE where the polymer matrix includes a polyimide, a silicon, a fluoropolymer, and/or copolymers of a polyimide-silicon. The process of the above-noted EXAMPLE where the ceramic particles includes hexagonal boron-nitride (h-BN) particles; and where the hexagonal boron-nitride (h-BN) particles includes 5 nm to 5 μm sized h-BN particles. The process of the above-noted EXAMPLE where the ceramic particles includes hexagonal boron-nitride (h-BN) particles; and where the hexagonal boron-nitride (h-BN) particles includes a filler within the composite coating material. The process of the above-noted EXAMPLE where the ceramic particles includes hexagonal boron-nitride (h-BN) particles; and where the hexagonal boron-nitride (h-BN) particles includes h-BN in forms of h-BN nano-particles, h-BN microparticles, h-BN nanotubes (NT), and/or h-BN pallets. The process of the above-noted EXAMPLE includes formulating the composite coating material to form a dispensed coating on one or more device parts. The process of the above-noted EXAMPLE includes formulating the composite coating material to form an inkjet coating on one or more device parts. The process of the above-noted EXAMPLE includes formulating the composite coating material to form a spray coating on one or more device parts. The process of the above-noted EXAMPLE includes formulating the composite coating material to form a screen printed coating on one or more device parts. The process of the above-noted EXAMPLE includes formulating the composite coating material to form a cured coating on one or more device parts.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A device comprising:
device parts;
a composite coating material arranged on one or more of the device parts; and
a molding compound arranged on and/or around one or more of the device parts,
wherein the composite coating material comprises a polymer matrix including and/or incorporating ceramic particles.

2. The device according to claim 1 wherein the molding compound is further arranged on one or more of the device parts implemented without the composite coating material coated thereon.

3. The device according to claim 1 wherein the device parts comprise one or more of a first lead, a second lead, at least one device component, a mount, at least one interconnect, a component attach, and/or at least one connection.

4. The device according to claim 1 wherein the device parts comprise at least one lead frame.

5. The device according to claim 1 wherein the composite coating material is arranged on all exposed surfaces of one or more of the device parts.

6. The device according to claim 1 wherein the composite coating material is arranged on surfaces of one or more of the device parts that contact the molding compound.

7. The device according to claim 1 wherein the composite coating material is formulated and/or configured to reduce failures of the device parts associated with interfacial stress exhibited during high temperature operation of the device.

8. The device according to claim 1 wherein the polymer matrix comprises a polyimide, a silicon, a fluoropolymer, and/or copolymers of a polyimide-silicon.

9. The device according to claim 1 wherein the ceramic particles comprise hexagonal boron-nitride (h-BN) particles; and wherein the hexagonal boron-nitride (h-BN) particles comprise 5 nm to 5 μm sized h-BN particles.

10. The device according to claim 1 wherein the ceramic particles comprise hexagonal boron-nitride (h-BN) particles; and wherein the hexagonal boron-nitride (h-BN) particles comprise a filler within the composite coating material.

11. The device according to claim 1 wherein the ceramic particles comprise hexagonal boron-nitride (h-BN) particles; and wherein the hexagonal boron-nitride (h-BN) particles comprise h-BN in forms of h-BN nano-particles, h-BN microparticles, h-BN nanotubes (NT), and/or h-BN pallets.

12. The device according to claim 1 wherein the composite coating material comprises a dispensed coating on one or more of the device parts.

13. The device according to claim 1 wherein the composite coating material comprises an inkjet coating on one or more of the device parts.

14. The device according to claim 1 wherein the composite coating material comprises a spray coating on one or more of the device parts.

15. The device according to claim 1 wherein the composite coating material comprises a screen printed coating on one or more of the device parts.

16. The device according to claim 1 wherein the composite coating material comprises a cured coating on one or more of the device parts.

17. The device according to claim 1 wherein the ceramic particles comprise hexagonal boron-nitride (h-BN) particles; and wherein the composite coating material comprises a mixture of at least the hexagonal boron-nitride (h-BN) particles and the polymer matrix.

18. The device according to claim 1 wherein the ceramic particles comprise hexagonal boron-nitride (h-BN) particles; and wherein the composite coating material comprises a mixture of at least the hexagonal boron-nitride (h-BN) particles and the polymer matrix together with other fillers.

19. The device according to claim 1 wherein the ceramic particles comprise hexagonal boron-nitride (h-BN) particles; and wherein the hexagonal boron-nitride (h-BN) particles comprise a surface functionalization.

20. The device according to claim 1 wherein the ceramic particles comprise hexagonal boron-nitride (h-BN) particles; and wherein the hexagonal boron-nitride (h-BN) particles are grafted to the polymer matrix.

21. The device according to claim 1 wherein the ceramic particles comprise hexagonal boron-nitride (h-BN) particles; and wherein the hexagonal boron-nitride (h-BN) particles comprise surface functionalization and the hexagonal boron-nitride (h-BN) particles are grafted to the polymer matrix.

22. The device according to claim 3 wherein the at least one device component comprises one or more MOSFETs and/or diodes.

23. The device according to claim 3 wherein the at least one device component comprises one or more active devices, passive devices, dies, chips, and/or transistors.

24. The device according to claim 3 wherein the at least one interconnect comprises one or more wires, wire bonds, and/or leads.

25. The device according to claim 1 wherein the device comprises a package, a power device package, and/or a power module.

26. A process of manufacturing a device comprising:
providing device parts;
arranging a composite coating material on one or more of the device parts; and
arranging a molding compound on and/or around one or more of the device parts,
wherein the composite coating material comprises a polymer matrix including and/or incorporating ceramic particles.

27.-36. (canceled)

37. The process of manufacturing a device according to claim 26 further comprising dispensing the composite coating material on one or more of the device parts to form a dispensed coating on one or more of the device parts.

38. The process of manufacturing a device according to claim 26 further comprising ink jetting the composite coating material on one or more of the device parts to form an inkjet coating on one or more of the device parts.

39. The process of manufacturing a device according to claim 26 further comprising spray coating the composite coating material on one or more of the device parts to form a spray coating on one or more of the device parts.

40. The process of manufacturing a device according to claim 26 further comprising screen printing the composite coating material on one or more of the device parts to form a screen printed coating on one or more of the device parts.

41. The process of manufacturing a device according to claim 26 further comprising curing the composite coating material on one or more of the device parts to form a cured coating on one or more of the device parts.

42.-43. (canceled)

44. The process of manufacturing a device according to claim 26 wherein the ceramic particles comprise hexagonal boron-nitride (h-BN) particles; and the process further comprising processing the hexagonal boron-nitride (h-BN) particles to form a surface functionalization.

45. The process of manufacturing a device according to claim 26 wherein the ceramic particles comprise hexagonal boron-nitride (h-BN) particles; and the process further comprising grafting the hexagonal boron-nitride (h-BN) particles to the polymer matrix.

46. The process of manufacturing a device according to claim 26 wherein the ceramic particles comprise hexagonal boron-nitride (h-BN) particles; and the process further comprising:
processing the hexagonal boron-nitride (h-BN) particles to form a surface functionalization; and
grafting the hexagonal boron-nitride (h-BN) particles to the polymer matrix.

47.-50. (canceled)
